(19) United States
(12) Patent Application Publication
(10) Pub. No.: US 2024/0304409 A1
(43) Pub. Date: Sep. 12, 2024

(54) PARTICLE BEAM MICROSCOPE

(71) Applicant: Carl Zeiss Microscopy GmbH, Jena (DE)

(72) Inventor: Erik Essers, Aalen (DE)

(21) Appl. No.: 18/600,313

(22) Filed: Mar. 8, 2024

(30) Foreign Application Priority Data
Mar. 10, 2023 (DE) 10 2023 106 025.2

(51) Int. Cl. H01J 37/244; H01J 37/14

(52) U.S. Cl. CPC H01J 37/244; H01J 37/14; H01J 2237/2443

(57) ABSTRACT

A particle beam microscope comprises an electron beam source, a beam tube, a magnetic objective lens having two pole ends, an object holder, a scintillator between the lower end of the beam tube and an object, a ring electrode between the scintillator and the object, and a potential supply system. The potential supply system provides: a potential U1 to the object holder; a potential U2 to the ring electrode; a potential U3 to the scintillator; and a potential to an electrically conductive inner lateral surface of the beam tube, such that U4>U1, U3>U1, U2>U1 and U2>U3.

### CROSS-REFERENCE TO RELATED APPLICATION

This application claims benefit under 35 U.S.C. § 119 to German Application No. 10 2023 106 025.2, filed Mar. 10, 2023. The entire disclosure of this application is incorporated by reference herein.

### FIELD

The present disclosure relates to particle beam microscopes, such as particle beam microscopes which comprise an electron beam source, a beam tube, a magnetic objective lens, an object holder and a scintillator. The electron beam source generates an electron beam whose electrons are accelerated, enter the beam tube at one end, exit it at the other end thereof and are incident on an object held on the object holder, with the electrons being retarded between the other end of the beam tube and the surface of the object. The electron beam incident on the object generates electrons there, for example secondary electrons and backscattered electrons, the intensity of which is detected and allows conclusions to be drawn about the structure of the object at the location of incidence of the electron beam on the object. The scintillator is part of a detector for detecting these electrons and is configured to generate light from electrons arriving from the object, the light being able to be converted into electrical signals by way of a light detector and the electrical signals allowing conclusions to be drawn about the intensity of the electrons generated at the object by the electron beam.

### BACKGROUND

In some situations, it can be desirable to detect a large proportion of the backscattered electrons generated at the object. These have a higher kinetic energy in comparison with the secondary electrons which are normally generated as well. The electrons generated at the object are accelerated in a direction away from the object in the electric field which retards the electrons moving toward the object. On account of their higher kinetic energy, the backscattered electrons can diverge greatly from the beam of electrons moving toward the object in this context. Therefore, it can be desirable to position the scintillator in the proximity of the point of incidence of the electron beam on the object in order to detect these backscattered electrons.

U.S. Pat. No. 9,029,766 B2 has disclosed a particle beam microscope of this type, the scintillator of which is arranged in the proximity of the object but within the beam tube and at the electric potential of the beam tube.

### SUMMARY

It was found that at least some conventional particle beam microscopes do not meet certain desired properties with respect to focusability of the electron beam on the surface of the object and with respect to the field of use for different types of particle beam-microscopic examinations.

The present disclosure proposes a particle beam microscope which comprises an electron beam source, a beam tube, a magnetic objective lens, an object holder and a scintillator and which has, by comparison, improved properties with respect to the focusability of the electron beam and/or with respect to the possible field of use.

According to an aspect of the disclosure, a particle beam microscope comprises an electron beam source, a beam tube, a magnetic objective lens, an object holder, a scintillator, a first ring electrode and a potential supply system. The electron beam source is configured to generate an electron beam whose electrons are accelerated to a high kinetic energy before they enter the beam tube. The beam tube comprises an electrically conductive inner lateral surface. The electron beam enters the beam tube at a first end thereof and exits the beam tube at a second end thereof. The magnetic objective lens serves to focus the electron beam in an object plane. The magnetic objective lens comprises a solenoid and a yoke with two pole ends, each extending around an axis of symmetry of the magnetic objective lens. A current flowing through the solenoid generates a magnetic field that exits the yoke at the pole ends and has a focusing effect on the electron beam. In addition to the focusing effect of the magnetic field generated by the magnetic objective lens, further magnetic and electrostatic fields may also be provided for the purpose of focusing the electron beam.

The object holder is configured to hold an object, which is intended to be examined via the particle beam microscope, in the object plane.

The scintillator is configured to generate light from electrons arriving from the object plane. This light can be detected by way of a light detector and can be converted into electrical signals. The electrons generate light in the scintillator by virtue of some of their kinetic energy being converted into light in the scintillator material of a scintillator body of the scintillator.

According to exemplary embodiments, the scintillator, as seen along a beam path of the electron beam or the axis of symmetry of the magnetic objective lens, is arranged between the second end of the beam tube and the object plane. For example, the scintillator is arranged at a distance from the second end of the beam tube in the direction of the beam path of the electron beam.

According to exemplary embodiments, the first ring electrode, as seen along the axis of symmetry, is arranged between the scintillator and the object plane. For example, an end of the ring electrode facing the object plane is arranged at a distance from the scintillator, as seen along the axis of symmetry.

According to exemplary embodiments, the particle beam microscope comprises a potential supply system which is configured to feed a first electric potential to the object holder, to feed a second electric potential to the first ring electrode, to feed a third electric potential to the scintillator and to feed a fourth electric potential to the electrically conductive inner lateral surface of the beam tube.

According to exemplary embodiments, at least one relation of the following group of four relations U4>U1, U3>U1, U2>U1 and U2>U3 is satisfied, where U1 represents the first potential, U2 represents the second potential, U3 represents the third potential and U4 represents the fourth potential. For example, two, three or all four relations of the group can also be satisfied.

According to exemplary embodiments, the potential of the ring electrode differs significantly from the potential of the scintillator. For example, this may hold true if the following relation is satisfied between the difference between the second potential U2 and the third potential U3, i.e. the potential difference between the ring electrode and the scintillator, and the difference between the fourth potential U4 and the first potential U1, i.e. the potential difference between the beam tube and the object:

$$( U 2 - U 3 ) > A * ( U 4 - U 1 ) ,$$

where A is equal to 0.05 or 0.07 or 0.10 or 0.15 or 0.2.

According to exemplary embodiments, the following also applies: U3>U4.

According to exemplary embodiments, the potential U3 of the scintillator is equal to the potential U4 of the beam tube.

According to exemplary embodiments, the potential U3 of the scintillator is substantially greater than the potential U4 of the beam tube. For example, the following relation may be satisfied between a difference between the third potential U3 and the fourth potential U4, i.e. the voltage between the scintillator and the beam tube, and a difference between the fourth potential U4 and the first potential U1, i.e. a voltage between the beam tube and the object:

$$( U 3 - U 4 ) > B * ( U 4 - U 1 ) ,$$

where B is equal to 0.05 or 0.07 or 0.10 or 0.15 or 0.2.

According to exemplary embodiments, the difference between the fourth potential U4 and the first potential U1, i.e. the voltage between the beam tube and the object, is greater than 4.0 kV and for example greater than 6.0 kV. This means that the electrons are incident on the object with a kinetic energy that is substantially smaller than the kinetic energy with which the electrons move in the beam tube.

According to exemplary embodiments, the second potential and the third potential, i.e. the potential U2 of the ring electrode and the potential U3 of the scintillator, and a distance between the ring electrode and the scintillator are chosen such that there is a significant electric field between the ring electrode and the scintillator. This significant field can be characterized by virtue of seeking for the location with the greatest electric field strength in a defined set of locations. For example, the defined set of locations may comprise the locations on the axis of symmetry of the magnetic objective lens. On account of the inhomogeneity of electric fields, the electric fields on the axis of symmetry are often substantially lower than at other locations between elements that generate electric fields. Therefore, in the example described here, the locations which are located on a cylinder surface around the axis of symmetry and which, as seen along the axis of symmetry, are located between the ring electrode and the scintillator are used to characterize the large electric field. The minimum distance between the second end of the beam tube and the axis of symmetry is used as radius for the cylinder surface. According to exemplary embodiments, the maximum electric field strength on this cylinder portion is greater than 200 kV/m.

An alternative characterization of the significant electric field strength can be implemented by virtue of seeking for the maximum electric field strength on a cylinder surface between the ring electrode and the scintillator, the cylinder radius of the cylinder surface being equal to the minimum distance between the ring electrode and the axis of symmetry. What may apply to this maximum electric field strength is that it is greater than for example 200 kV/m.

According to exemplary embodiments, the potential supply system comprises a voltage divider having a first resistor and a second resistor. The first resistor connects the electrically conductive inner lateral surface of the beam tube to the scintillator; otherwise, these parts are insulated from one another. The second resistor connects the scintillator and the ring electrode; otherwise, these parts are insulated from one another. By using the voltage divider, it is easily possible to feed different electric potentials to the three components of beam tube, scintillator and ring electrode, without having to use three different high-voltage sources to this end.

According to exemplary embodiments, the first resistor and the second resistor are arranged in the interior of a vacuum jacket of the particle beam microscope. As a result, it is possible to supply the three components of beam tube, scintillator and ring electrode with three different high voltage potentials without to this end needing to provide three separate high-voltage feedthroughs through the vacuum jacket. The vacuum jacket of the particle beam microscope is evacuable by way of a vacuum pump, and at least the electron beam source, the scintillator and the ring electrode are arranged in the interior thereof.

According to exemplary embodiments, the beam tube comprises an electrically insulating body having an inner wall and an outer wall. An electrically conductive layer can be provided on the inner wall of the electrically insulating body and forms the electrically conductive inner lateral surface of the beam tube. The potential supply system may comprise at least one conductor track which is provided on the electrically insulating body and is carried by the latter. The conductor track is electrically insulated in relation to the electrically conductive layer on the inner wall of the electrically insulating body. The scintillator and/or the ring electrode can be electrically connected to the at least one conductor track. The embodiment of the beam tube as electrically insulating body and the attachment of the at least one conductor track to the electrically insulating body allows an electric potential which differs from the electric potential having the interior of the beam tube to be fed to the scintillator and/or the ring electrode. For example, this manner of feeding potential to the scintillator and/or the ring electrode can avoid laying separate wires through the objective lens to the scintillator and to the ring electrode, which are arranged in a very restricted installation space within the objective lens.

According to exemplary embodiments, the at least one conductor track comprises a first conductor track electrically connected to the scintillator and a second conductor track electrically connected to the ring electrode. The first and the second conductor track can be arranged within the electrically insulating body at different distances from the axis of symmetry. For example, the electrically insulating body may to this end comprise two insulating hollow bodies fitted into one another, one of which carries the first conductor track and the other carries the second conductor track. It is also possible that the first conductor track and the second conductor track are provided spaced apart in the circumferential direction in the electrically insulating body.

According to exemplary embodiments, the electrically insulating body, on the inner wall of which the electrically conductive layer forming the electrically conductive inner lateral surface of the beam tube is provided and which carries the at least one conductor track, may also be used independently of the scintillator and the ring electrode of the embodiments described above in order to feed electric potentials to other elements arranged in the proximity of the end of the beam tube. In this case, too, a potential supply system may be provided, which comprises a voltage divider which feeds electric potentials to the elements arranged in the proximity of the end of the beam tube via the conductor track or the plurality of conductor tracks on the electrically insulating body.

According to exemplary embodiments, the potential supply system is also configured to feed a fifth electric potential to the electron beam source, where U4>U5 applies, where U4 represents the fourth electric potential, i.e. represents the potential of the beam tube, and U5 represents the fifth potential, i.e. represents the potential of the electron beam source. According to exemplary embodiments, a difference between the fourth and the fifth potential, i.e. a voltage between the electron beam source and the beam tube, is significant and for example greater than 4.0 kV, such as greater than 6.0 kV. This means that the electrons of the electron beam are accelerated to a significant kinetic energy, with which they enter the beam tube.

According to exemplary embodiments, the particle beam microscope comprises a first beam deflector and a second beam deflector. The first beam deflector, as seen along the axis of symmetry of the magnetic objective lens, is arranged between the electron beam source and the scintillator, and the second beam deflector, as seen along the axis of symmetry of the magnetic objective lens, is arranged between the first beam deflector and the scintillator. The particle beam microscope may also comprise a controller for supplying the first beam deflector and the second beam deflector with excitations, which each lead to a deflection of the electron beam which passes through the first and the second beam deflector in sequence. The first beam deflector and the second beam deflector may be considered together as a double deflector. The first and the second beam deflector may comprise electrostatic beam deflectors or magnetic beam deflectors or a combination of electric and magnetic beam deflectors. For excitation purposes, magnetic beam deflectors are fed with currents that generate magnetic fields, which deflect the electron beam, in coils. For excitation purposes, electrostatic beam deflectors are fed with voltages that generate electric fields, which lead to the deflection of the electron beam, between electrodes.

According to exemplary embodiments, the controller is configured to control the first and the second beam deflector such that an angle at which the electron beam is incident on the object plane can be varied within a range of at least 1° and for example 5° and a location at which the electron beam is incident on the object plane can be varied within a region of at least 10 μm×10 μm. This means that the first and the second beam deflector can be controlled to scan the electron beam over the region with dimensions of at least 10 μm×10 μm and/or to modify the direction from which the electron beam is incident on the object plane by at least 1° at each location, wherein the direction can be set independently of the location at which the electron beam is incident on the object plane.

Interesting object examinations can be performed using a particle beam microscope configured thus, for example on account of the option of being able to vary the angle at which the electron beam is incident on the object plane in the aforementioned large range. However, this control of the electron beam can involve a large internal diameter of the ring electrode and the scintillator, which is why these each have a central hole, the diameter of which is optionally greater than 0.7 mm, greater than 1.0 mm, greater than 1.5 mm or greater than 2.0 mm. In some embodiments, the central hole of the ring electrode is larger than the central hole in the scintillator. The diameter of the central hole of the ring electrode is chosen in view of the detection of the backscattered electrons and in view of the formation of the electric field between the scintillator and the ring electrode. For example, the diameter of the central hole of the ring electrode is in a range from 2.0 mm to 4.0 mm or from 3.0 mm to 6.0 mm. A distance along the axis of symmetry between the side of the scintillator facing the object plane and the end of the ring electrode facing the object plane may for example range between 0.5 mm and 6.0 mm. A comparatively large region of the cross section of the central hole of the scintillator is scanned by the electron beam in the case of the aforementioned deflection of the electron beam with variation in the location and the angle. It is desirable that the effects of the electric fields with respect to focal changes and generation of astigmatism are small over the entire region of the cross section. The diameter of the central hole in the scintillator and of the central hole in the ring electrode are designed in view of reducing these effects.

Together with the described supply of the components with the electric potentials, the arrangement of the scintillator between the second end of the beam tube and the ring electrode allows a reduction in the electric field strength and the location-dependent change in the electric field strength in the opening of the scintillator. The reduction in the inhomogeneities of the electric field in the radial direction with respect to the axis of symmetry achieved thereby improves the focusing of the electron beam in the object plane and the spatial resolution of the particle beam microscope, especially if the particle beam moves at a distance from the axis of symmetry. The arrangement of the scintillator between the end of the beam tube and the ring electrode and the supply of these elements with the aforementioned voltages thus allow the interesting examinations with different angles of incidence of the electron beam on the object to be performed with a high spatial resolution.

According to exemplary embodiments, the particle microscope also comprises a first electron detector, which comprises the scintillator and a light detector which is configured to detect light generated by the scintillator and to generate electrical signals corresponding to the detected light. The first electron detector may also comprise a light guide which is arranged in a beam path of the light generated by the scintillator, wherein the light guide has a light entry surface which, as seen along the axis of symmetry of the magnetic objective lens, is arranged between the electron beam source and the scintillator. According to exemplary embodiments, the light entry surface of the light guide, as seen along the axis of symmetry of the magnetic objective lens, is arranged between the electron beam source and an edge of the solenoid of the objective lens located closest to the electron beam source. This means that the light entry surface, as seen along the axis of symmetry of the magnetic objective lens, is arranged between the electron beam source and the component of the objective lens, specifically the solenoid. This configuration allows detection of the light generated by the scintillator without the provision of a light guide that passes through the yoke of the objective lens.

According to exemplary embodiments, the light guide has a hole through which the beam path of the electron beam passes.

According to exemplary embodiments, the particle beam microscope may comprise a second electron detector which has an electron receiver surface which, as seen along the axis of symmetry of the magnetic objective lens, is arranged between the electron beam source and a beam deflector of the particle beam microscope. Electrons incident on the electron receiver surfaces of this second electron detector have passed through the scintillator through the central hole thereof. These electrons differ from the electrons detected by the scintillator in terms of their kinetic energy and in terms of the direction with which they started from the object. For example, these electrons also comprise secondary electrons.

Embodiments of the disclosure will be explained in detail below with reference to figures.

### BRIEF DESCRIPTION OF THE DRAWINGS

FIG. 1 shows a schematic sectional representation of a particle beam microscope according to a first embodiment.

FIG. 2 shows a schematic sectional representation of a portion of a particle beam microscope according to a second embodiment.

FIG. 3 shows an enlarged representation of a part of FIG. 2.

FIG. 4 shows a schematic sectional representation of a portion of a particle beam microscope according to a third embodiment.

### DETAILED DESCRIPTION

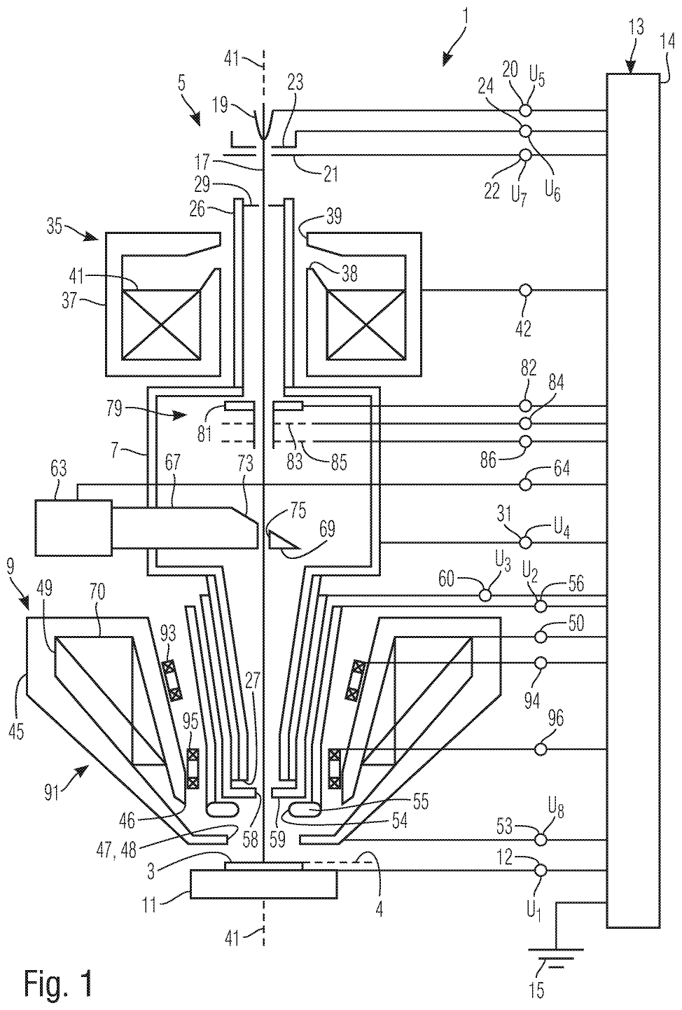

FIG. 1 shows a schematic sectional representation of a particle beam microscope 1 according to a first embodiment, which can be used for microscopic examinations of an object 3. The particle beam microscope 1 comprises an electron beam source 5, a beam tube 7, a magnetic objective lens 9, an object holder 11 and a control system 13. The control system 13 provides numerous functionalities for the operation of the particle beam microscope 1. These functionalities comprise the provision of electric potentials with a high voltage with respect to earth. To this end, the control system 13 comprises a potential supply system 14, which can generate high voltages with respect to an earth 15 and can output these at appropriate outputs.

The functionalities of the control system 13 also comprise the provision of excitations, for example potential differences and currents, which are fed to components, for instance lenses and beam deflectors of the particle beam microscope, in order to influence the particle beam. To this end, the control system 13 comprises a current and voltage supply system, which provides the voltages and currents at appropriate outputs.

The functionalities of the control system 13 also comprise obtaining data from individual components of the particle beam microscope 1, for example from detectors which detect electrons and other signals generated in the particle beam microscope.

The object 3 to be examined using the particle beam microscope 1 is attached to the object holder 11 and positioned relative to the magnetic objective lens 9 as a result thereof, wherefore the object holder 11 may comprise actuators not depicted in the figure. Via a terminal 12, the object holder 11 and the object 3 in contact with the object holder 11 are fed with an electric potential U1 by the potential supply system 14. In the example under discussion here, the potential U1 is equal to the earth potential 15, and so the object 3 has a voltage of 0 V with respect to the earth 15.

The electron beam source 5 comprises an electron emitter 19 which emits the electrons that form the electron beam 17. Via a terminal 20, the electron emitter 19 is kept at a potential U5 by the potential supply system 14. A difference between the potential U5 of the electron emitter 19 and the potential U1 of the object 3 determines the kinetic energy with which the electrons of the electron beam 17 are incident on the surface of the object 3.

To promote the emission of electrons by the electron emitter 19, the latter may for example be heated by a heater (not shown in FIG. 1). Moreover, via a terminal 22, an extractor 21 of the electron beam source 5 is fed with a potential U7 by the potential supply system 14 in order to generate a high electric field strength at a tip of the electron emitter 19 which releases electrons from the latter. Further, this electric field is shaped by a suppressor electrode 23, which is fed with a suitable electric potential U6 by the potential supply system 14 via a terminal 24.

The beam tube 7 has a first end 25, at the top in FIG. 1, and a second end 27, at the bottom in FIG. 1. An anode stop 29 with an opening through which the electron beam 17 enters the beam tube is formed at the first end 25 of the beam tube 7. The beam tube has an electrically conductive inner lateral surface, with the result that the inner surface of the entire beam tube 7 is at the same electric potential U4, which is fed via a terminal 31 by the potential supply system 14. Hence, the electrons of the electron beam 17 pass through the beam tube 7 from the first end 25 of the beam tube 7 to the second end 27 of the beam tube 7 without changing their kinetic energy in the process. A difference between the potentials U4 and U1 can be greater than 4.0 kV or greater than 6.0 kV. In the example described here, this difference is equal to 8.0 kV. Hence, the kinetic energy of the electrons of the electron beam 17 within the beam tube 7 is substantially greater than the kinetic energy with which the electrons are incident on the surface of the object 3. Accordingly, the electrons pass through the beam tube from the first end 25 to the second end 27 within a short period of time, wherefore a deterioration in the quality of the electron beam on account of the electrostatic repulsion of the electrons in the beam from one another is small.

The electrons emitted by the electron emitter 19 are collimated by the effects of the electrostatic fields provided by the extractor 21, the suppressor electrode 23 and the anode 29 and also by a condenser 35 which provides a focusing magnetic field. The condenser 35 comprises a yoke 37 with two pole ends 38 and 39 which extend around an axis of symmetry 41 that coincides with the electron beam 17 in FIG. 1. Provided in the yoke 37 is a solenoid 49 which is fed with an excitation current by the control system 13 via a terminal 42 in order to generate a magnetic field, which focuses the electron beam 17, between the two pole ends 38, 39. Further, an aperture stop, not depicted in FIG. 1, is provided in the beam path of the electron beam 17 between the suppressor electrode 23 and the objective lens 9, in order to limit the beam cross section and the beam current of the electron beam 17.

The magnetic objective lens 9 comprises a yoke 45 with two pole ends 46 and 47, which are arranged spaced apart from one another and extend around the axis of symmetry 41. Provided within the yoke is the solenoid 49 which is fed with an excitation current by the control system 13 via a terminal 50 in order to generate a magnetic field which emerges from the yoke 45 at the pole ends 46, 47 and focuses the electron beam 17.

The yoke 45 is kept at a potential U8 by the potential supply system 14 via a terminal 53, this potential being equal to the potential U1 and hence equal to the earth potential 15 in the example under discussion here. However, it is possible to provide potentials different from one another for the potentials U1 and U8.

An electrostatic field which retards the electrons of the electron beam 17 before they are incident on the surface of the object 3 is created between the second end 27 of the beam tube 7 and the pole end 47. This retarding electrostatic field is inhomogeneous and also acts on the electron beam 17 in focusing fashion as an electrostatic lens. This electrostatic lens and the magnetic objective lens 9 and the collimator 35 provide lenses for imaging a tip of the electron emitter 19 on an object plane 4, in which the surface of the object 3 is arranged.

Provided between the second end 27 of the beam tube 7 and the object plane 4 is a first ring electrode 55 which is fed with an electric potential U2 by the potential supply system 14 via a terminal 56, this potential being different from the potential U8 of the yoke 45 of the magnetic objective lens 9 and from the potential U4 of the beam tube 7.

An electric field substantially determined by the difference between the potential U2 of the first ring electrode 55 and the potential U8 of the pole end 47 and the distance between the first ring electrode 55 and the pole end 47 in the direction of the axis of symmetry 41 is created between the pole end 47 and the first ring electrode 55. By virtue of the pole end 47 determining this electric field acting on the electron beam 17, the pole end 47 can also be considered to be a second ring electrode 48.

Further, arranged between the lower end 27 of the beam tube 7 and the ring electrode 55 is a scintillator 59 which is fed with a potential U3 by the potential supply system 14 via a terminal 60, this potential being different from the potential U2 of the ring electrode and possibly being different from the potential U4 of the beam tube.

One or more of the following relations may apply to the potentials U1, U2, U3 and U4: U4>U1, U3>U1, U2>U1, U2>U3, U3>U4,
(U2−U3)>A*(U4−U1) and (U3−U4)>B*(U4−U1), where A is equal to 0.05 or 0.07 or 0.10 or 0.15 or 0.2 and B is equal to 0.05 or 0.07 or 0.10 or 0.15 or 0.2.

According to one example, the potentials are chosen as follows:
U1=0 V, U2=10.0 kV, U3=9.0 kV and U4=8.0 kV.

Secondary electrons and backscattered electrons are generated at the object 3 as a result of the electrons of the electron beam 17 being incident on the object 3. The secondary electrons have a low kinetic energy and are accelerated in the direction towards the electron beam source 5 in the electric field between the surface of the object 3 and the ring electrode 55, without deviating far from the axis of symmetry 41, with the result that they pass through the central opening 54 in the ring electrode 55 and a central opening 58 in the scintillator 59 and enter the beam tube 7 at the second end 27 thereof. The backscattered electrons generated at the object 3 are also accelerated in the direction towards the electron beam source 5 in the electric field between the surface of the object 3 and the ring electrode 55; however, on account of their higher kinetic energy, these may deviate further from the axis of symmetry 41, and so a significant portion of the backscattered electrons is incident on the scintillator 59.

The scintillator 59 comprises a body made of a scintillator material, for example a YAP scintillator material or a P47 scintillator material. At least the surface of the scintillator 59 facing the object plane is provided with an electrically conductive layer, with the result that this surface is at the potential U3. For example, a thin metallic layer, which reflects light but allows the electrons arriving from the object 3 to enter into the scintillator material of the scintillator 59, is vapour deposited onto this surface. Light is generated in the scintillator material from electrons arriving from the object 3.

Some of the light generated by the scintillator 59 is detected by a light detector 63, which may for example comprise a photomultiplier, a photodiode, an avalanche diode, an avalanche diode array or the like. The light detector 63 converts the light generated by the scintillator 59 into electrical signals, which are transmitted to the control system 13 via a terminal 64. The light generated by the scintillator 59 reaches the light detector 63 by virtue of leaving the scintillator material of the scintillator 59 upwardly in FIG. 1, in the direction towards the electron beam source 5, and entering a light guide 67. The light guide 67 has a light entry surface 69 which is arranged between the electron beam source and the objective lens 9 in the beam path of the electron beam 17. For example, the light entry surface 69 of the light guide 67 is arranged closer to the tip of the electron emitter 19 than an edge 70 of the solenoid 49 of the magnetic objective lens 9 closest to the electron beam source 5. The light entering the light guide 67 via the light entry surface 69 is internally reflected at a reflective surface 73 of the light guide 67, to be precise in the direction towards the light detector 63 such that the light can be detected by the latter.

The surfaces of the scintillator 59 through which the generated light exits towards the light detector can be coated in electrically conductive and/or light-transmissive fashion. A coating of these surfaces which is both electrically conductive and light-transmissive can be formed from ITO (indium tin oxide). The surfaces of the scintillator arranged such that light exiting through them does not reach the light detector may have an electrically conductive and/or light-reflecting coating. A coating of these surfaces which is both electrically conductive and light-reflective can be formed from aluminium.

The light guide 67 has a hole 75 through which the electron beam 17 passes such that the light entry surface 69 surrounds the electron beam 17 in ring-shaped fashion.

The scintillator 59, the light guide 67 and the light detector 63 jointly form a first electron detector for detecting electrons which are generated at the object 3 by the electron beam 17 incident on the object 3.

Some of the electrons emanating from the object 3 and generated by the incident electron beam 17 pass through the opening 54 in the ring electrode 55 and the opening 58 in the scintillator 59 and also through the hole 75 in the light guide 67 and can be detected by a second electron detector 79. The second electron detector 79 is arranged between the electron beam source 5 and the magnetic objective lens 9 in the beam path of the electron beam 17. The second electron detector 79 can be an electron detector of any desired suitable construction. For example, the second electron detector 79 may comprise a semiconductor detector 81 which converts incident electrons into electrical signals, which are transmitted to the control system 13 via a terminal 82. A grid 83 and a grid 85 may be arranged upstream of the semiconductor detector 81 in the beam path of the electrons arriving from the object 3 and these grids are fed with adjustable electric potentials by the potential supply system 14 via terminals 84 and 86, respectively. These electric potentials bring about adjustable filtering of the electrons detected by the detector 79 with respect to their kinetic energy. For example, it is thus possible, by suitably setting the potentials at the grids 83 and 85, to detect only backscattered electrons generated at the object 3 which have a kinetic energy greater than an adjustable minimum energy.

As seen along the beam path of the electron beam 17 or the axis of symmetry 41, a double deflector 91, which comprises a first beam deflector 93 and a second beam deflector 95, is provided between the object plane 4 and the light receiver surface 69 of the light guide 67 or the second electron detector 79. As seen in the direction of the axis of symmetry 41, the first and the second beam deflector 93, 95 are arranged at a distance from one another. Via terminals 94 and 96, respectively, the two beam deflectors 93 and 95 are fed with adjustable excitations by the control system 13 in order to deflect the electron beam 17 passing through the beam deflectors 93 and 95 through two adjustable deflection angles. In the depicted example, the beam deflectors 93 and 95 are magnetic beam deflectors which comprise coils fed with adjustable excitation currents via the terminals 94 and 96 in order to generate magnetic fields that deflect the electron beam 17. However, the beam deflectors 93 and 95 can also be electrostatic beam deflectors which comprise opposing electrodes fed with adjustable potentials via the terminals 94 and 96, in order to generate electric fields that deflect the electron beam 17.

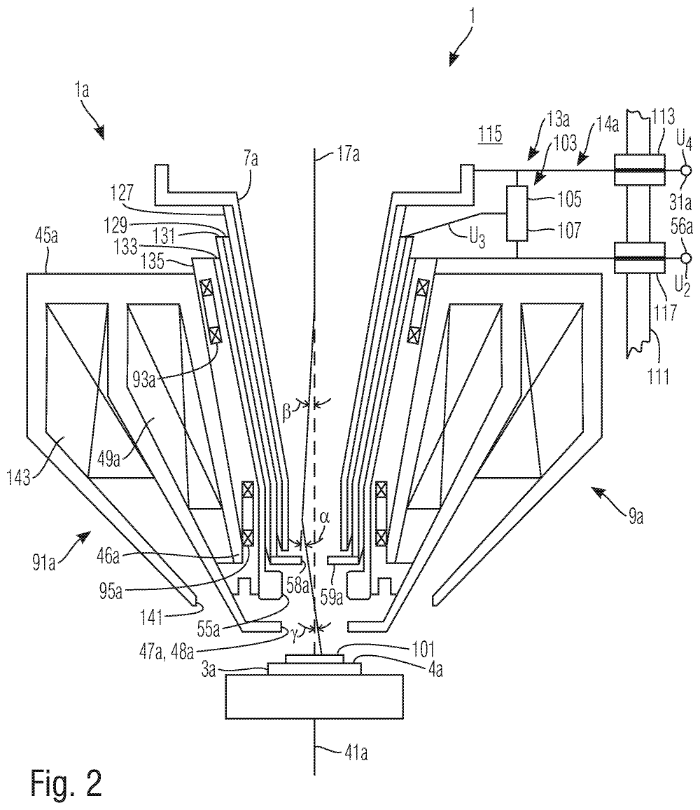

FIG. 2 is a schematic sectional representation of a portion of a particle beam microscope 1a according to a second embodiment. In comparison with the particle beam microscope 1, the particle beam microscope 1a has a few differences, which are further explained hereinbelow. Otherwise, the particle beam microscope 1a is substantially identical to the particle beam microscope 1, and so its components are not explained again.

A function of the beam deflection of an electron beam 17a is explained below on the basis of FIG. 2, resulting in the electron beam being able to be directed at any desirably selectable location within a region 101 in an object plane 4a, in which a surface of an object 3a is arranged. The region 101 may have a size of 10 μm×10 μm, for example.

The beam deflection is implemented using a double deflector 91a which comprises a first beam deflector 93a through which the electron beam 17a passes and a second beam deflector 95a which the electron beam 17a passes through after the first beam deflector 93a. An excitation of the beam deflector 93a set by a control system (not depicted in FIG. 2) deflects the electron beam 17a passing through the beam deflector 93a through an angle β, and an excitation of the beam deflector 95a set by the control system deflects the electron beam 17a passing through the beam deflector 95a through an angle α, with the result that the electron beam 17a is able to be incident at any desirably selectable location within the region 101 in the object plane 4a, wherein an angle of incidence 7 as angle between the electron beam 17a and a straight line orthogonal to the object plane 4a can also be set. For example, this angle of incidence γ of the electron beam 17a on the object plane 4a is adjustable in a range from −1° to +10.

It is evident that the electron beam 17a does not always pass centrally through an opening 58a in a scintillator 59a and may pass through the opening 58a at a location with a significant distance from an axis of symmetry 41a of an objective lens 9a, with respect to which the opening 58a in the scintillator 59a is also centred. With regards to good focusing of the particle beam 17a in the object plane 4a, it is desirable for the electric field strength in the radial direction not to vary too strongly within the opening 58a. This could be achieved by virtue of choosing the diameter of the opening 58a in the scintillator 59a to be substantially larger than the region within the opening 58a through which the electron beam 17a passes. However, it is also desirable to keep the size of the opening 58a small so that the area of the scintillator 59a available for the detection of electrons is large.

Therefore, the electron-optical components located upstream and downstream of the scintillator 59a in the direction of the electron beam 17a, specifically a lower end of a beam tube 7a and a first ring electrode 55a, are used to shape the field in the region of the opening 58a in the scintillator 59a such that it is relatively homogeneous in the radial direction. This is achieved by virtue of the scintillator 59a being at the potential U3 which is higher than the potential U4 of the lower end of the beam tube 7a and which is lower than the potential U2 of the first ring electrode 55a. For such an arrangement, a thin scintillator, for example thinner than the diameter of its opening 58a, thinner than the radius of its opening 58a or thinner than half the radius of its opening 58a, has an additional positive influence on the variation of the electric field strength in the radial direction within the opening 58a.

The central opening 58a of the scintillator 59a may have a diameter of more than 0.7 mm, more than 1.0 mm, more than 1.5 mm or more than 2.0 mm, for example. For example, the central opening 54a in the ring electrode 55a may be bigger than 2.0 mm and smaller than 4.0 mm or 6.0 mm. For example, a distance between the lower sides of the scintillator 59a and the ring electrode 55a can be greater than 0.5 mm and less than 6.0 mm. A thickness of the ring electrode 55a measured along the axis of symmetry 41 can be greater than 0.5 mm or greater than 1.0 mm, for example, and it can be less than 15 mm or less than 10 mm.

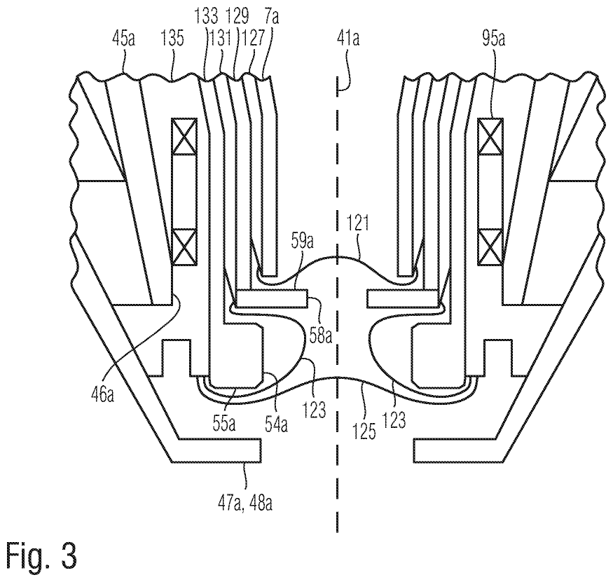

FIG. 3 is an enlarged representation of a portion of FIG. 2, in which the scintillator 59a and components arranged in the proximity thereof are depicted.

For one example, in which the potential U4 is equal to 8 kV, the potential U3 is equal to 9 kV, the potential U2 is equal to 10 kV and the potential U8 of a second ring electrode 48a formed by a pole end of a yoke 45a of the objective lens 9a is 0 V (earth), lines 121, 123, 125 are used in FIG. 3 to schematically depict potential lines of a few potentials that are useful for the explanation. The line 121 represents the course of the equipotential surface at the potential of 8.5 kV. The equipotential surface represented by the line 121 passes through the axis of symmetry 41a and opens into an insulator 127 which electrically insulates a holder 129 of the scintillator 59a from the beam tube 7a. The line 123 represents the course of the equipotential surface at the potential of 9.1 kV. The equipotential surface represented by the line 123 surrounds the axis of symmetry 41a and opens firstly, at the top in FIG. 3, into an insulator 131 which electrically insulates a holder 133 of the ring electrode 55a from the scintillator 59a and secondly, at the bottom in FIG. 3, into an insulator 135 which electrically insulates the holder 133 of the ring electrode 55a from the yoke 45a of the objective lens 9a. The potential line 125 represents the course of the potential of 8.0 kV. The equipotential surface represented by the line 125 passes through the axis of symmetry 41a and also opens into the insulator 135.

The potentials U2 and U3 and the distance in the direction of the axis of symmetry 41a are chosen such that significant electric fields arise that noticeably influence the trajectories and the speeds along the trajectories of the electrons that were generated by the electron beam 17a at the object 3a and have passed through the opening in the second ring electrode 48a or in the pole end 47a in order to be detected. These electrons can be detected when they are incident on the scintillator 59a and generate light or when they pass through the opening 58a in the scintillator 59a and are detected by a detector located downstream of the scintillator 59a in the beam path of these electrons. To characterize the strength of the electric fields it is possible to use a relation whereby a maximum electric field strength on a cylinder portion is greater than 200 kV/m, wherein the cylinder portion is given by locations that have a distance from the axis of symmetry 41a equal to the minimum distance of the beam tube 7a at its lower end from the axis of symmetry 41a and that are located between the ring electrode 55a and the scintillator 59a in the direction of the axis of symmetry 41a. In the case of an exactly circular cross section of the beam tube 7a at its lower end, the minimum distance of the beam tube 7a from the axis of symmetry 41a is equal to the inner radius of the beam tube 7a. Alternatively, the cylinder portion can be chosen to have a different radius such that the latter is equal to the minimum distance of the ring electrode 55a from the axis of symmetry 41a. In the case of a circular inner edge of the ring electrode 55a, the radius of the cylinder is equal to the inner radius of the ring electrode 55a.

It was found that the equipotential surfaces passing through the axis of symmetry have a relatively little curvature in an extended region surrounding the axis of symmetry 41a, with the result that the electron beam 17a, when passing through this extended region surrounding the axis of symmetry 41a, is influenced substantially in similar fashion by the prevalent electric fields, independently of the distance from the axis of symmetry 41a. Hence, the focusing of the electron beam 17a on the surface of the object 3a is modified to only a small extent when the location at which the electron beam 17a is incident on the object 3a is changed and when the angle at which the electron beam 17a is incident on the object 3a is changed. This is achieved by the design of the electric potentials U4>U1, U3>U1, U2>U1 and U2>U3, without the diameter of the opening 58a in the scintillator being particularly large. Consequently, a large surface of the scintillator facing the object 3a is available for detecting electrons.

On account of this design of the lower end of the beam tube 7a, of the scintillator 59a, of the first ring electrode 55a and of the second ring electrode 48a, the electrons emanating from the surface of the object 3a are initially accelerated through an opening in the second ring electrode 48a towards the first ring electrode 55a and are slightly retarded towards the scintillator after passing through the opening in the first ring electrode 55a. Some of these electrons are subsequently incident with slight retardation on the surface of the scintillator 59a and effectively detected by the latter on account of the nevertheless sufficiently high kinetic energy of the electrons. Another portion of these electrons passes through the opening 58a in the scintillator, is further retarded towards the lower end of the beam tube 7a and enters the beam tube 7a in order to be possibly detected by a second detector, like the detector 79 shown in FIG. 1.

If the electron beam 17a of the particle beam microscope 1a is used to scan an image field, i.e. a region 101, with a very large number of pixels, then a disturbance of the focusing of the electron beam 17a on the surface of the object 3a with increasing deflection of the electron beam 17a away from the axis of symmetry 41a can be increasingly visible due to aberrations, for instance defocus and astigmatism, changing with the axial distance. Even if a measurement is taken at the same point on the sample with a very large number of different angles of incidence using the electron beam 17a of the particle beam microscope 1a, then a disturbance of the focusing of the electron beam 17a on the surface of the object 3a with increasing angular deflection of the electron beam 17a can become increasingly noticeable due to aberrations, for instance defocus and astigmatism, changing in the process. To compensate the astigmatism, the control system 13 can cause, depending on the deflection of the electron beam 17a, an excitation of an electrostatic or magnetic quadrupole field (not shown) in both cases, the quadrupole field acting on the electron beam 17a and compensating the deflection-dependent change in astigmatism. To compensate the defocus, the control system 13 can cause, depending on the deflection of the electron beam 17a, an excitation of an electrostatic or magnetic lens in both cases, the lens acting on the electron beam 17a and compensating the deflection-dependent defocus. In this case, the deflection can be a deflection of the beam position of the electron beam 17a on the surface of the object 3a or an angular deflection which changes the angle of incidence of the electron beam 17a on the surface of the object 3a. In both cases, the deflection is set with the aid of the excitations of the first beam deflector 93 and/or the second beam deflector 95.

A difference between the particle beam microscope 1a and the particle beam microscope 1 of FIG. 1 is now explained on the basis of FIG. 2.

In the particle beam microscope 1a, a control system 13a with a potential supply system 14a comprises a voltage divider 103 having a first resistor 105 and a second resistor 107 in order to generate an electric potential U3 of a scintillator by voltage division from an electric potential U4 of the beam tube 7a and the electric potential U2 of the first ring electrode 55a. Via a terminal 31a located outside of a vacuum jacket 111, the electric potential U4 is guided via an electric vacuum bushing 113 into an interior of a vacuum space 115 delimited by the vacuum jacket 111 to the beam tube 7a. Via a terminal 56a located outside of a vacuum jacket 111, the electric potential U2 is guided via an electric vacuum bushing 117 into the interior of the vacuum space 115 to the first ring electrode 55a. An electron beam source (not shown in FIG. 2), the scintillator 59a, the ring electrode 55a and further electron-optical components of the particle beam microscope 1a are arranged in the interior of the vacuum space 115. The particle beam microscope 1 of FIG. 1 also has such a vacuum space 115 delimited by a vacuum jacket 111 not shown in FIG. 1. However, the voltage divider 103 is also arranged in the interior of the vacuum space 115 of the particle beam microscope 1a. The voltage divider 103 is used to generate the electric potential U3 within the vacuum space 115 without the potential having to be supplied from outside of the vacuum space 115 via a separate terminal, like the terminal 60 of the particle beam microscope 1 of FIG. 1, and an additional vacuum bushing through the vacuum jacket 111.

In the embodiment shown in FIG. 2, the ring electrode 55a is attached to the end of the holder 133 facing the object plane and extends radially inwardly from the ring-shaped end of the holder 133 towards the axis of symmetry 41a in order to define the opening in the ring electrode through which the electron beam passes. This leads to the diameter of the opening in the ring electrode being smaller than the inner diameter of the holder 133 at the latter's end facing the object plane. However, further embodiments provide for the ring electrode to be provided by the end of the holder facing the object plane or by another tubular component, with the result that the inner diameter of the ring electrode corresponds to the inner diameter of the end of the holder facing the object plane or of the other tubular component.

The insulator 127 is an insulating body with, provided on its inner wall, an electrically conductive layer that forms the inner lateral surface of the beam tube 7a and with, provided on its outer wall, an electrically conductive body that forms the holder 129 of the scintillator 59a and provides the conductor track connecting the scintillator 59a to the potential supply system 14. Hence, in addition to the holder for the conductive inner lateral surface of the beam tube 7a, the insulator 127 also provides a mechanical holder for a further element, specifically the scintillator 59a, and an electrical connection for this element. In other embodiments, this further element may be different from a scintillator.

For example, in such embodiments, the ring electrode can be the further element which is carried on the beam tube and electrically contacted so that its electric potential is different from the electric potential of the inner wall of the beam tube. Moreover, two or more conductor tracks that are insulated from one another can be provided on the outer wall of the insulator, which tracks extend from, in FIG. 2, the upper end of the insulator to its lower end in order to supply different electric potentials to two or more components arranged within the magnetic objective lens in the region of the lower second end of the beam tube. In comparison with the conventional supply of corresponding potentials by insulated wires, this may be advantageous since the installation space within the objective lens is limited in this region and the electric fields present may lead to creepage currents and flashovers. For example, this allows two conductor tracks which are insulated from one another to be used on the outer side of the insulating body in order to supply different potentials to the scintillator and the ring electrode. Moreover, it is possible, as seen along the axis of symmetry, to provide one further or more further ring electrodes between the scintillator and the object plane, the further ring electrode or electrodes being able to be independently supplied with adjustable electric potentials by way of an appropriate number of conductor tracks in order to adapt the electric fields within the objective lens even more accurately to existing desired properties.

A further difference between the embodiment shown in FIG. 2 and the embodiment of FIG. 1 is that the magnetic objective lens 9a comprises a yoke 45a with three pole ends 46a, 47a and 141, which are arranged at a distance from one another and extend around the axis of symmetry 41a. An inner solenoid 49a and an outer solenoid 143 are provided within the yoke and supplied by the control system 13a with excitation currents in order to generate magnetic fields which emerge from the yoke 45a at the pole ends adjacent to the respective solenoid 49a, 143 and which focus the electron beam 17a. In this case, the second ring electrode 48a is formed by the pole end 47a whose portion of the yoke extends outside of the inner solenoid 49a and within the outer solenoid 143.

As seen along the axis of symmetry 41a, the magnetic field of the inner solenoid 49a substantially acts on the electron beam 17a in a region above the second ring electrode 48a. The advantage of the magnetic field of the inner solenoid 49a over the magnetic field of the outer solenoid 143 is that it has a low intensity in a region in which the object 3a is arranged and is therefore well suited, for example, for the examination of magnetic samples and the implementation of EBSD (electron backscatter diffraction) examinations.

A further advantage of the use of the magnetic field generated by the inner solenoid 49a consists of the fact that the electron beam 17a can be focused substantially more easily therewith than with the magnetic field generated by the outer solenoid 143, even in the case of a high landing energy of the electrons of the electron beam 17a on the object 3a and in the case of a short distance between the object plane 4a and the ring electrode 48a.

As seen along the axis of symmetry 41a, the magnetic field of the outer solenoid 143 substantially acts in a region below the second ring electrode 48a. Compared to the magnetic field of the inner solenoid 49a, the advantage of the magnetic field of the outer solenoid 143 is that it keeps the secondary electrons emanating from the object 3a in the proximity of the axis of symmetry 41a and thus facilitates their passage through the opening 58a in the scintillator 59a. This advantage can be particularly noticeable in the case of a middling and large distance between the object plane 4a and the ring electrode 48a. In contrast to the magnetic field of the inner solenoid 49a, the magnetic field of the outer solenoid 143 can also prevent slow and near-axis backscattered electrons from striking the scintillator 59a.

It is possible to omit the outer solenoid 143 and the portion of the yoke 45a outside of the outer solenoid 143 in order to obtain a magnetic objective lens similar to in FIG. 1. Alternatively, it is also possible in the embodiment of FIG. 2 to omit the inner solenoid 49a and the portion of the yoke 45a within the inner solenoid 49a. Such embodiments with only one solenoid in the objective lens are advantageous in that more installation space is available for this one solenoid and its yoke and that less compromises have to be made when designing the geometry of the objective lens.

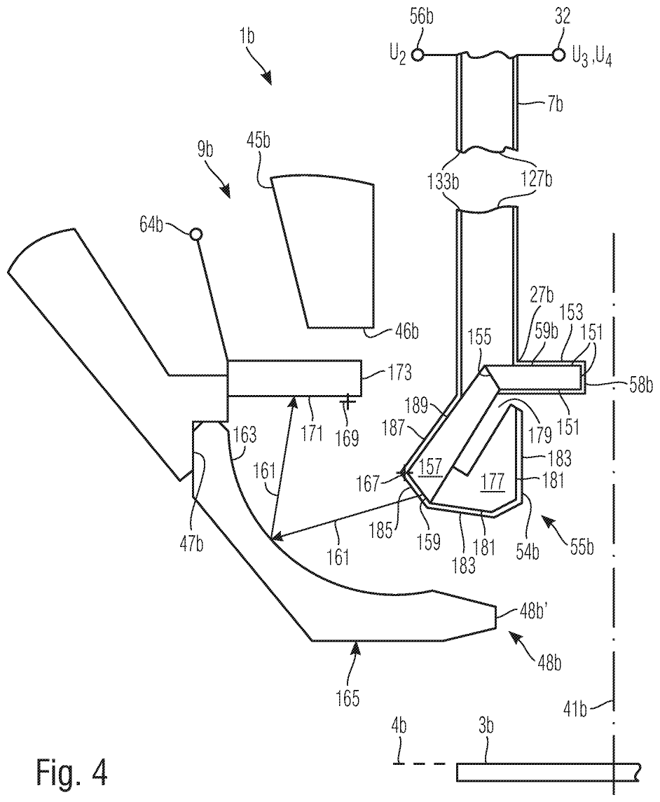

FIG. 4 is a schematic sectional representation of a portion of a particle beam microscope 1b according to a third embodiment. In comparison with the particle beam microscopes 1 and 1a, the particle beam microscope 1b has a few differences, which are further explained hereinbelow. Otherwise, the particle beam microscope 1b is substantially identical to the particle beam microscopes 1 and 1a, and so its components are not explained again. In FIG. 4, components which correspond to those of the first and the second embodiment in terms of their structure or function are provided by the same reference signs as in FIGS. 1 to 3, although the lowercase “b” has been added to the components of the third embodiment.

Similar to FIG. 3, FIG. 4 only depicts components arranged in the proximity of pole ends 46b, 47b of a yoke 45b of a magnetic objective lens 9b and in the proximity of an object 3b, with the sectional representation merely showing the components on one side of an axis of symmetry 41b, around which the yoke 45b with the pole ends 46b and 47b extends.

An insulating tube 127b has an inner wall provided with an electrically conductive layer which forms the inner lateral surface of a beam tube 7b, which, via a terminal 32, is fed with an electric potential U4 by a potential supply system. At a lower end 27b of the beam tube 7b, a scintillator 59b is attached to the insulating tube 127b. The scintillator material of the scintillator 59b has the form of a plane-parallel plate which is punctured by a circular opening 58b that is symmetric with respect to the axis of symmetry 41b.

Surfaces 151 of the scintillator 59b, specifically the surface 151 of the scintillator 59b pointing upwards in FIG. 4, the surface 151 facing the axis of symmetry 41b and the surface 151 of the scintillator 59b pointing downwards in FIG. 4, are provided with an electrically conductive layer 153 which is electrically connected to the beam tube 7b such that the surface of the scintillator 59b is at an electric potential U3 which is the same as the electric potential U4 of the inner lateral surface of the beam tube 7b.

A light guide 157 is optically coupled to a surface 155 of the scintillator 59b located externally radially in relation to the axis of symmetry 41b. With respect to the axis of symmetry 41b, the light guide 157 extends radially outwardly and toward an object plane 4b. The light guide 157 may be formed in one piece and extend around the axis of symmetry 41b or it may consist of a plurality of segments which are arranged distributed around the axis of symmetry 41b. Electrons which are generated by an electron beam focused on the object 3b by the objective lens 9b and which penetrate into the scintillator 59b generate light that is intended to be detected.

In the embodiments of FIGS. 1 to 3, some of the light generated in the scintillator leaves the scintillator upwardly in the figures in order to be detected by a light detector which, as seen along the axis of symmetry, is arranged between the scintillator and the source of the electron beam. In the exemplary embodiment of FIG. 4, the coating 153 provided on the surfaces 151 of the scintillator 59b is not only electrically conductive but also light-reflective, with the result that a large proportion of the light generated in the scintillator 59b enters the light guide 157 via the surface 155 of the scintillator 59b. This light can emerge from a light exit surface 159 of the light guide, with one exemplary light ray 161 of this light being depicted in FIG. 4. The light ray 161 is incident on a mirror surface 163 of a mirror 165 held on the pole end 47b. In the sectional representation of FIG. 4 containing the axis of symmetry 41b, the mirror surface 163 has the form of a part of an ellipse with foci 167 and 169, wherein the mirror surface 163 is symmetric with respect to the axis of symmetry 41b by virtue of extending around the latter.

The light ray 161 is incident on a surface 171 of a light detector 173 likewise held on the pole end 47b. Detection signals generated by the light detector 173 are output via a terminal 64b to a controller of the electron microscope 1b. These detection signals represent detections of electrons by the scintillator 59b.

A ring-shaped body 177 made of an electrically insulating material is fastened to the light guide 157 in the region of an end of the light guide 157 distant from the scintillator 59b. The ring-shaped body 177 is designed such that it extends inwardly, towards the axis of symmetry 41b, and upwardly, towards the scintillator 59b, with a gap 179 remaining between the light guide 157 and the ring-shaped body 177 in the region of an end of the light guide 157 close to the scintillator 59b.

Surfaces 181 of the ring-shaped body 177 not adjoining the gap 179 are provided with an electrically conductive layer 183. The electrically conductive layer 183 is electrically conductively connected to a layer 185 which covers the light exit surface 159 and is electrically conductive and light-transmissive. The layer 185 in turn is electrically conductively connected to an electrically conductive layer 187, which covers an outer surface 189 of the light guide 157. The layer 187 is electrically conductively connected to a layer 133b which is provided on the outer surface of the insulating tube 127b and, via a terminal 56b, is fed with a potential U2 by the potential supply system. Hence the electrically conductive layer 183 on the ring-shaped body 177 forms a first ring electrode 55b with an opening 54b, which is at the potential U2.

A further ring electrode 48b is formed by the mirror 165 with an opening 48b′ which is symmetric to the axis of symmetry 41b and is at the same potential as the pole end 47b and yoke of the objective lens 9b.

The relations described above may apply between the potential U2 of the first ring electrode 55b, the potential U3 of the scintillator 59b, the potential U4 of the beam tube and a potential U1 fed to the object 3b, wherein U3=U4 applies in the embodiment shown in FIG. 4.

1. A particle beam microscope, comprising:
an electron beam source configured to generate an electron beam;
a beam tube comprising an electrically conductive inner lateral surface, a first end and a second end, the beam tube configured so that the electron beam enters the beam tube at the first end and emerges from the beam tube at the second end;
a magnetic objective lens configured to focus the electron beam in an object plane, the magnetic objective lens comprising a solenoid and a yoke, the yoke comprising first and second pole ends, each of the first and second pole ends extends around an axis of symmetry of the magnetic objective lens;
an object holder configured to hold an object in the object plane;
a scintillator configured to generate light from electrons arriving from the object plane and which, along the axis of symmetry, is between the second end of the beam tube and the object plane;
a first ring electrode comprising an end facing the object plane, the ring electrode being between the scintillator and the object plane along the axis of symmetry; and
a potential supply system configured to provide: a potential U1 to the object holder; a potential U2 to the first ring electrode; a potential U3 to the scintillator; and a potential U4 to the electrically conductive inner lateral surface of the beam tube,
wherein U4>U1, U3>U1, U2>U1 and U2>U3.

2. The particle beam microscope of claim 1, wherein:
$$( U 2 - U 3 ) > A * ( U 4 - U 1 ) ;$$
A is equal to a member selected from the group consisting of 0.05, 0.07, 0.10, 0.15 and 0.2.

3. The particle beam microscope of claim 1, wherein U3≥U4.

4. The particle beam microscope of claim 3, wherein:
$$( U 3 - U 4 ) > B * ( U 4 - U 1 ) ;$$
B is equal to a member selected from the group consisting of 0.05, 0.07, 0.10, 0.15 and 0.2.

5. The particle beam microscope of claim 1, wherein (U4−U1)>4.0 kV.

6. The particle beam microscope of claim 1, wherein:
the second end of the beam tube has a minimum distance from the axis of symmetry; and
between the first ring electrode and the scintillator, a maximum electric field strength is greater than 200 kV/m at locations arranged at the minimum distance.

7. The particle beam microscope of claim 1, wherein:
the potential supply system comprises a voltage divider comprising a first resistor and a second resistor;
the first resistor is connected between the electrically conductive inner lateral surface of the beam tube and the scintillator; and
the second resistor is connected between the scintillator and the first ring electrode.

8. (canceled)

9. The particle beam microscope of claim 1, wherein:
the first ring electrode has a minimum distance from the axis of symmetry; and
along the axis of symmetry between the ring electrode and the scintillator, a maximum electric field strength is greater than 200 kV/m at locations arranged at the minimum distance from the axis of symmetry.

10. The particle beam microscope of claim 1, wherein:
the beam tube comprises an electrically insulating body comprising an inner wall and an outer wall;
the inner wall comprises an electrically conductive layer defining the electrically conductive inner lateral surface of the beam tube;
the potential supply system comprises at least one conductor track supported by the electrically insulating body; and
the scintillator and/or the ring electrode is electrically connected to the at least one conductor track.

11. (canceled)

12. The particle beam microscope of claim 1, wherein:
the potential supply system is configured to provide a potential U5 to an electron emitter of the electron beam source; and
U4>U5.

13. (canceled)

14. The particle beam microscope of claim 1, further comprising:
a first beam deflector which, along the axis of symmetry, is between the electron beam source and the scintillator; and
a second beam deflector which, along the axis of symmetry, is between the first beam deflector and the scintillator.

15. (canceled)

16. The particle beam microscope of claim 1, wherein the scintillator comprises a central opening having a diameter of more than 0.7 mm.

17. The particle beam microscope of claim 1, wherein the ring electrode comprises a central opening having a diameter of more than 2.0 mm and/or less than 6.0 mm.

18. The particle beam microscope of claim 1, wherein a distance along the axis of symmetry between a side of the scintillator facing the object plane and the end of the ring electrode facing the object plane is greater than 0.5 mm and/or is less than 6.0 mm.

19. The particle beam microscope of claim 1, further comprising a first electron detector comprising the scintillator and a light detector, wherein the light detector is configured to: detect light generated by the scintillator; and generate electrical signals corresponding to the detected light.

20. The particle beam microscope of claim 19, wherein:
the first electron detector further comprises a light guide between the scintillator and the light detector in a beam path of the light generated by the scintillator; and
the light guide comprises a light entry surface which, along the axis of symmetry, is between the electron beam source and the scintillator.

21. (canceled)

22. (canceled)

23. The particle beam microscope of claim 1, further comprising:
a beam deflector which, along the axis of symmetry, is between the electron beam source and the scintillator; and
a second electron detector comprising an electron receiver surface which, along the axis of symmetry, is between the electron beam source and the beam deflector.

24. The particle beam microscope of claim 1, wherein:
the electron beam is exposed to the potential U3;
no electrostatic shield, shielding the electron beam from the electric potential of the scintillator, is between the electron beam and the scintillator.

25. The particle beam microscope of claim 1, further comprising a further element in proximity to the second end of the beam tube, wherein:
the potential supply system is configured to feed an electrical potential to the further element;
the beam tube comprises an electrically insulating body comprising an inner wall and an outer wall;
the inner wall of the electrically insulating body comprises an electrically conductive layer defining the electrically conductive inner lateral surface of the beam tube;
the potential supply system comprises at least one conductor track which differs from the electrically conductive layer;
the electrically insulating body supports the at least one conductor track; and
the at least one further element is electrically connected to the at least one conductor track.

26.-30. (canceled)

31. A particle beam microscope, comprising:
an electron beam source configured to generate an electron beam;
a beam tube comprising an electrically conductive inner lateral surface, a first end and a second end, the beam tube configured so that the electron beam enters the beam tube at the first end and emerges from the beam tube at the second end;
a magnetic objective lens configured to focus the electron beam in an object plane, the magnetic objective lens comprising a solenoid and a yoke, the yoke comprising first and second pole ends, each of the first and second pole ends extends around an axis of symmetry of the magnetic objective lens;
an object holder configured to hold an object in the object plane;
a further element in proximity to the second end of the beam tube;
a potential supply system configured to provide electrical potentials to the object holder, the further element and the electrically conductive inner lateral surface of the beam tube, wherein:
the beam tube comprises an electrically insulating body comprising an inner wall and an outer wall;
the inner wall of the electrically insulating body comprises an electrically conductive layer defining the electrically conductive inner lateral surface of the beam tube;
the potential supply system comprises at least one conductor track which differs from the electrically conductive layer;
the electrically insulating body supports the at least one conductor track; and
the at least one further element is electrically connected to the at least one conductor track.

32.-47. (canceled)
